(19) United States
(12) Patent Application Publication
(10) Pub. No.: US 2005/0258509 A1
(43) Pub. Date: Nov. 24, 2005

(54) Substrate, semiconductor device, and substrate fabricating method

(76) Inventors: Yasuyoshi Horikawa, Nagano-shi (JP); Noriyoshi Shimizu, Nagano-shi (JP)

Correspondence Address: LADAS & PARRY LLP, 224 SOUTH MICHIGAN AVENUE, SUITE 1600, CHICAGO, IL, 60604, US

(21) Appl. No.: 11/132,062

(22) Filed: May 18, 2005

(30) Foreign Application Priority Data
May 21, 2004 (JP) 2004-152341

(51) Int. Cl. H01L 29/00

(52) U.S. Cl. 257/531

(57) ABSTRACT

A substrate is disclosed that includes an inductor that is realized by first wiring, and resin including high magnetic permeability filler material that covers the first wiring.

### BACKGROUND OF THE INVENTION

1. Field of the Invention

The present invention relates to a substrate including an inductor, a semiconductor device, and a method of fabricating such a substrate.

2. Description of the Related Art

In recent years and continuing, with the development of techniques for increasing functions of an electronic apparatus and achieving higher integration in the electronic apparatus, a technique is being developed for providing a passive element such as an inductor, a capacitor, and/or a resistor in a multilayer wiring substrate. Also, with the demand for miniaturization of the electronic apparatus, miniaturization of the substrate is also demanded.

It is noted that an inductor may be mounted on wiring of a substrate as a chip inductor component (surface mount inductor) or wiring of a substrate that is shaped into a loop or a spiral structure may be provided with functions of an inductor (embedded inductor) (see Japanese Laid-Open Patent Publication No. 2003-243570). According to an example, the inductor may be combined with a capacitor to realize functions of a filter such as a low pass filter or a high pass filter and conduct selection of a predetermined frequency.

In another example, the inductor may be used in a radio wave transmission/reception antenna provided for an IC card. It is noted that the inductor as is described above preferably has high inductance. Also, it is noted that chip components such as a semiconductor element or a chip capacitor may be mounted on the substrate as is described above.

In a case where a surface mount inductor is used, although high inductance may be realized in the chip inductor component, a mounting region for the chip inductor component has to be provided on the substrate, and thereby, miniaturization of the substrate may be difficult.

In a case where the embedded inductor is used, wiring having a long wiring length has to be provided in the substrate in order to realize high inductance, and thereby, miniaturization of the substrate may be difficult.

### SUMMARY OF THE INVENTION

The present invention has been conceived in response to one or more of the problems of the related art, and its object is to provide a substrate and a semiconductor device having a miniaturized inductor and realizing high inductance. Also, it is an object of the present invention to provide a method for fabricating such a substrate.

According to an aspect of the present invention, a substrate is provided that includes an inductor that is realized by first wiring, and resin including high magnetic permeability filler material that covers the first wiring.

According to an embodiment of the present invention, by covering the first wiring with the resin including high magnetic permeability filler material, high inductance may be achieved in the inductor, and miniaturization of the inductor may be realized.

According to an embodiment, the substrate of the present invention includes second wiring that is provided at a region positioned above a region at which the first wiring is formed, the second wiring being electrically connected to the first wiring, wherein the resin including high magnetic permeability filler material is arranged to cover the second wiring.

According to an embodiment of the present invention, by forming the second wiring covered by the resin including high magnetic permeability filler material above the first wiring rather than forming the first and second wirings on the same plane, a long wiring length may be secured for the wiring realizing the inductor to thereby achieve high inductance in the inductor and realize miniaturization of the inductor.

According to an embodiment of the present invention, the resin corresponds to electrodeposited resin that is formed through electrodeposition.

According to an embodiment of the present invention, by using electrodeposited resin that is formed through electrodeposition, the thickness of the resin including high magnetic permeability filler material that covers the first wiring and/or the second wiring may be easily controlled, and even when the first wiring and/or the second wiring correspond to micro-wirings, the resin including high magnetic permeability filler material may be suitably formed to cover the first wiring and/or the second wiring.

According to another aspect of the present invention, a semiconductor device is provided that includes a substrate including an inductor that is realized by first wiring, and resin including high magnetic permeability filler material which resin covers the first wiring, and a semiconductor element that is mounted on the substrate.

According to an embodiment of the present invention, by providing a miniaturized inductor having high inductance, the performance of the semiconductor device may be improved.

According to another aspect of the present invention, a method of fabricating a substrate including an inductor realized by wiring is provided, the method including a wiring formation step for forming the wiring, and an electrodeposited resin formation step for forming resin including high magnetic permeability filler material through electrodeposition which resin covers the wiring.

According to an embodiment of the present invention, by forming the resin including high magnetic permeability filler material that covers the wiring, high inductance may be achieved in the inductor and miniaturization of the inductor may be realized. Also, by using the electrodeposition method, the thickness of the resin including high magnetic permeability filler material that covers the wiring may be easily controlled, and even when the wiring corresponds to micro-wiring, the resin including high magnetic permeability filler material may be suitably formed to cover the wiring.

According to an embodiment of the present invention, the wiring formation step includes a first wiring formation step for forming first wiring, and a second wiring formation step for forming second wiring that is provided at a region positioned above a region at which the first wiring is formed, the second wiring being electrically connected to the first wiring, and a space is created between the first wiring and the second wiring.

According to an embodiment of the present invention, by forming the second wiring covered by the resin including high magnetic permeability filler material above the first wiring rather than forming the first and second wirings on the same plane, a long wiring length may be secured for the wiring realizing the inductor to thereby achieve high inductance in the inductor and realize miniaturization of the inductor.

### BRIEF DESCRIPTION OF THE DRAWINGS

FIG. 1 a cross-sectional diagram showing a configuration of a semiconductor device according to a first embodiment of the present invention;

FIG. 2 is a plan view showing a configuration of an inductor of the semiconductor device shown in FIG. 1;

FIG. 3 is a cross-sectional diagram showing a configuration of the inductor shown in FIG. 2;

FIG. 4 is a cross-sectional diagram showing a configuration of a semiconductor device having an inductor formed within an internal layer portion of a buildup layer;

FIG. 5 is a diagram illustrating a wiring formation process step for forming the inductor shown in FIG. 2;

FIG. 6 is a diagram illustrating an electrodeposited resin formation process step for forming the inductor shown in FIG. 2;

FIG. 7 is a diagram illustrating a first process step for forming the electrodeposited resin on selected wiring portions;

FIG. 8 is a diagram illustrating a second process step for forming the electrodeposited resin on selected wiring portions;

FIG. 9 is a diagram illustrating a third process step for forming the electrodeposited resin on selected wiring portions;

FIG. 10 is a plan view showing a configuration of an inductor according to a second embodiment of the present invention;

FIG. 11 is a cross-sectional diagram showing a configuration of the inductor shown in FIG. 10;

FIG. 12 is a diagram illustrating a first process step for forming the inductor of the second embodiment;

FIG. 13 is a diagram illustrating a second process step for forming the inductor of the second embodiment;

FIG. 14 is a diagram illustrating a third process step for forming the inductor of the second embodiment;

FIG. 15 is a diagram illustrating a fourth process step for forming the inductor of the second embodiment;

FIG. 16 is a diagram illustrating a fifth process step for forming the inductor of the second embodiment;

FIG. 17 is a diagram illustrating a sixth process step for forming the inductor of the second embodiment;

FIG. 18 is a diagram illustrating a seventh process step for forming the inductor of the second embodiment;

FIG. 19 is a diagram illustrating an eighth process step for forming the inductor of the second embodiment;

FIG. 20 is a diagram illustrating a ninth process step for forming the inductor of the second embodiment; and

FIG. 21 is a diagram illustrating a tenth process step for forming the inductor of the second embodiment.

### DETAILED DESCRIPTION OF THE PREFERRED EMBODIMENTS

In the following, preferred embodiments of the present invention are described with reference to the accompanying drawings.

### First Embodiment

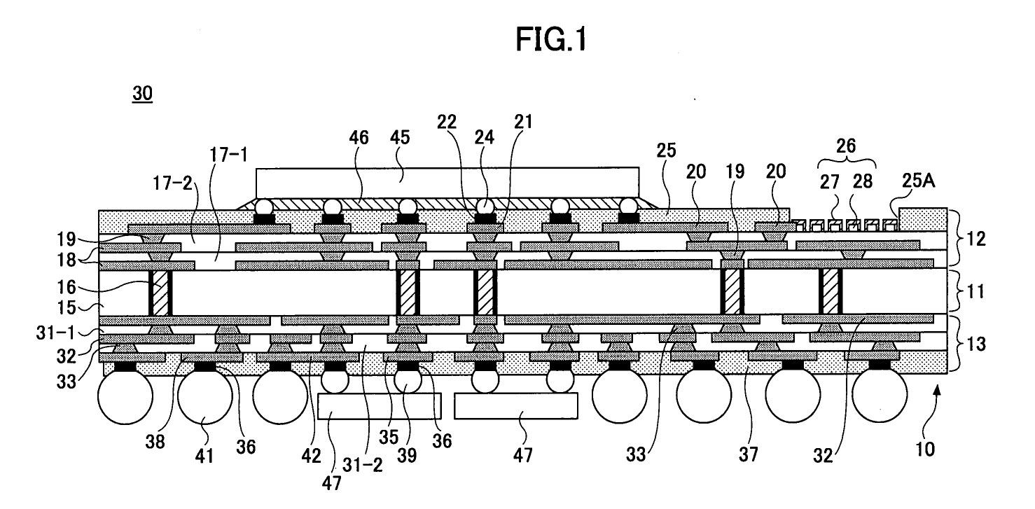

In the following, a semiconductor device 30 according to a first embodiment of the present invention is described with reference to FIG. 1.

FIG. 1 is a cross-sectional diagram showing a configuration of the semiconductor device 30 according to the first embodiment. As is shown in FIG. 1, the semiconductor device 30 includes a substrate 10, a LSI chip 45 including solder bumps 24, and a chip capacitor 47.

The LSI chip 45, which corresponds to a semiconductor element, has a multilayer wiring structure including plural wiring layers and insulating layers (not shown). The LSI 45 is flip-chip connected to the substrate 10 via the solder bumps 24, and an under-fill resin 46 is provided between the LSI chip 45 and the substrate 10. The under-fill resin 46 is provided in order to control influences created by a mismatch between the thermal expansion coefficients of the LSI chip 45 and the substrate 10. The chip capacitor 47 is provided for absorbing noise of a power source such as a CPU of the LSI chip 45. The chip capacitor 47 is electrically connected to the substrate 10 via solder balls 39.

The substrate 10 includes a core substrate 11, buildup layers 12, 13, solder balls 39, 41, and an inductor 26. The core substrate 11 has a multilayer wiring structure including a resin base material 15, via holes (filled with conductive material but simply referred to as via hole hereinafter) 16, and plural internal layer wirings and via holes (not shown). The substrate 10 may correspond to a printed wiring board, for example. The via holes 16 penetrate through the base material 15 and are arranged to realize electrical connection between the buildup layers 12 and 13.

The buildup layer 13 is formed on the lower surface of the core substrate 11. The buildup layer 13 includes resin layers 31-1 and 31-2 that correspond to insulating layers, Cu wirings 32 and 42, via holes 33, connection pads 35 and 38 that are made of a CU film, dispersion prevention films 36, a solder resist layer 37, and solder balls 39 and 41. It is noted that plural Cu wirings 32 and via holes 33 are provided at the resin layers 31-1 and 31-2, and the via holes 33 are arranged to realize electrical connection between the Cu wirings 32 and 42 provided at the upper side and the lower side, respectively.

The solder resist layer 37 is arranged to expose the connection pads 35 and 38, and cover the Cu wiring 42. The dispersion prevention films 36 are provided between the connection pads 35/38 and the solder balls 39/41. The dispersion prevention films 36 are provided to prevent the Cu included in the connection pads 35 and 38 from being dispersed into the solder balls 39 and 41, and improve solder wettability. In one example, the dispersion prevention films 36 may have a Ni/Au dual layer structure. The solder balls 41 may be provided in order to mount the semiconductor device 30 on a mounting substrate such as a mother board. The solder balls 39 are provided in order to realize connection with the chip capacitor 47.

The buildup layer 12 is formed on the upper surface of the core substrate 11. The buildup layer 12 includes resin layers 17-1 and 17-2 that correspond to insulating layers, Cu wirings 18 and 20, via holes 19, connection pads 21 that are made of a CU film, dispersion prevention films 22, a solder resist layer 25, and an inductor 26. It is noted that plural Cu wirings 18 and via holes 19 are provided at the resin layers 17-1 and 17-2, and the via holes 19 are arranged to realize electrical connection between the Cu wirings 18 and 20 provided at the upper side and the lower side, respectively.

The solder resist layer 25 is arranged to expose the connection pads 21, and cover the Cu wiring 20. The dispersion prevention films 22 are provided between the connection pads 21 and the solder bumps 24. The dispersion prevention films 22 are provided to prevent the Cu included in the connection pads 21 from being dispersed into the solder bumps 24, and improve solder wettability. In one example, the dispersion prevention films 22 may have a Ni/Au dual layer structure.

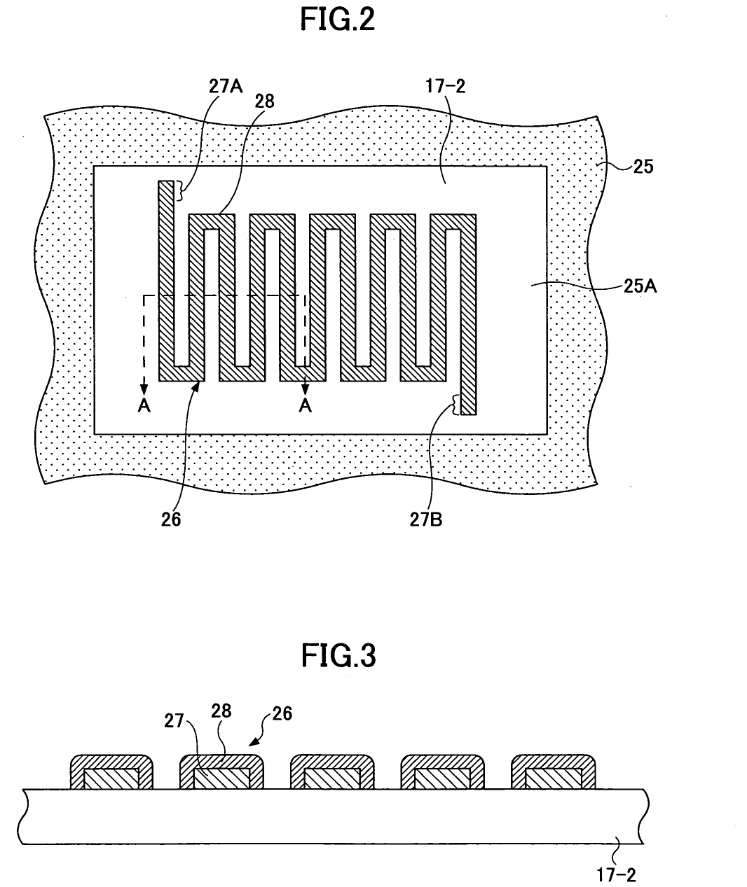

In the following, the inductor 26 is described in detail with reference to FIGS. 2 and 3.

FIG. 2 is a plan view of the inductor 26 shown in FIG. 1, and FIG. 3 is a cross-sectional view of the inductor 26 cut across line A-A of FIG. 2.

The inductor 26 includes Cu wiring 27 and electrodeposited resin 28. The Cu wiring 27 is formed on the resin layer 17-2 and is exposed from an opening 25A formed at the solder resist layer 25. The Cu wiring 27 corresponding to first wiring is arranged into a comb-shaped structure in order to secure a long wiring length. Also, it is noted that end portions 27A and 27B of the Cu wiring 27 are electrically connected to the lower wiring 18 through the via holes 19.

The electrodeposited resin 28 corresponds to resin including high magnetic permeability filler material. The electrodeposited resin 28 is arranged to cover the upper and side surfaces of the Cu wiring 27. It is noted that polyimide resin or epoxy resin may be used as the electrodeposited resin 28, for example. Also, it is noted that the magnetic permeability of the high magnetic permeability material included in the electrodeposited resin 28 is preferably greater than or equal to 100.

In the following, the inductance (L) of the inductor 26 is described.

The inductance (L) of a conductor (i.e., Cu wiring 27 in the present example) with radius (a), length (l), and permeability (μₐ) that is provided within a medium B with permeability (μ_{b}) (i.e., electrodeposited resin 28 in the present example) may be obtained by the following formula (1):

$$L = \frac{l}{2 π} \{ \frac{{μ}_{a}}{4} + {μ}_{b} ( ln \frac{2 l}{a} - 1 ) \} \qquad ( 1 )$$

As can be appreciated from the above formula (1), the permeability (μ_{b}) of the electrodeposited resin 28 may be increased in order to increase the inductance (L) per unit length of the Cu wiring 27 making up to inductor 26.

Accordingly, by covering the Cu wiring 27 with the electrodeposited resin 28 including a high magnetic permeability filler material as is described above, a higher inductance may be achieved in the inductor 26 according to the present embodiment compared to an inductor of the prior art that only includes wiring, and the inductor 26 may be miniaturized. Also, the inductor mounting region for mounting the inductor 26 on the substrate 10 may be reduced in size. It is noted that the electrodeposited resin 28 is formed through an electrodeposition process, and thereby, the thickness of the electrodeposited resin 28 may be easily controlled. By controlling the thickness of the electrodeposited resin 28, desired inductance may be achieved.

It is noted that ferrite (permeability μ=2000), Fe, Ni, Fe—Ni alloy, or Permalloy, for example, may be used as the high magnetic permeability material. Also, it is noted that the filler made of the high magnetic permeability material may be arranged to have a dimension of a few μm or lower, for example.

Also, it is noted that in an experiment, the inductor 26 of the substrate 10 was formed using ferrite (permeability μ=2000) as the high magnetic permeability filler material. It was found from this experiment that the inductance per length unit of the inductor 26 could be increased by up to several dozen times with respect to the conventional inductor that only includes wiring.

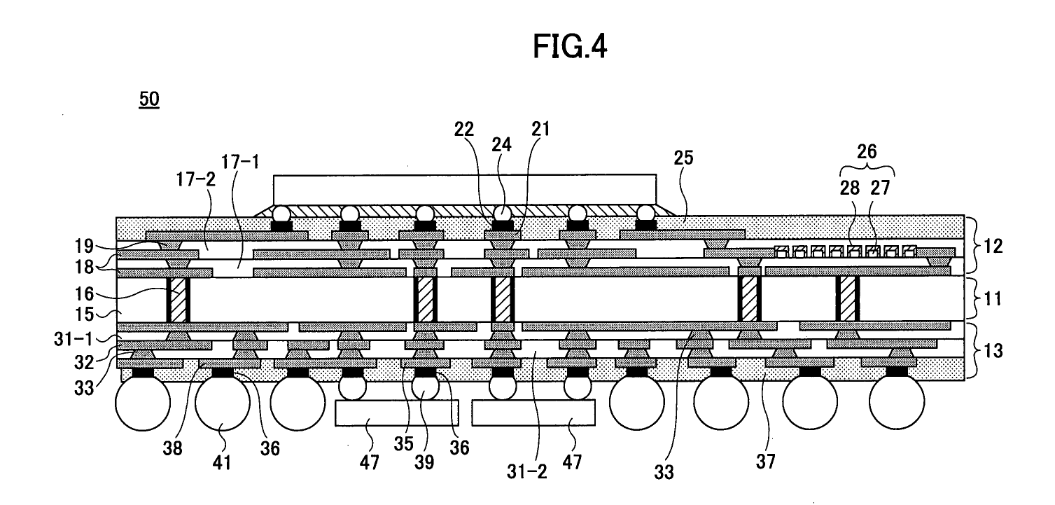

It is noted that in FIGS. 1˜3, the inductor 26 is formed on the resin layer 17-2 corresponding to the uppermost layer of the buildup layer 12. However, the present invention is not limited to such an arrangement, and for example, the inductor 26 may be provided in an internal layer portion of the buildup layer 12 as is the case for a semiconductor device 50 that is shown in FIG. 4. In another example, the inductor 26 may be provided at an outer layer or internal layer portion of the buildup layer 12.

FIG. 4 is a cross-sectional diagram showing a configuration of the semiconductor device 50 having an inductor provided within an internal layer portion of a buildup layer. It is noted that in FIG. 4, components that are identical to those showing in FIG. 1 are assigned the same references.

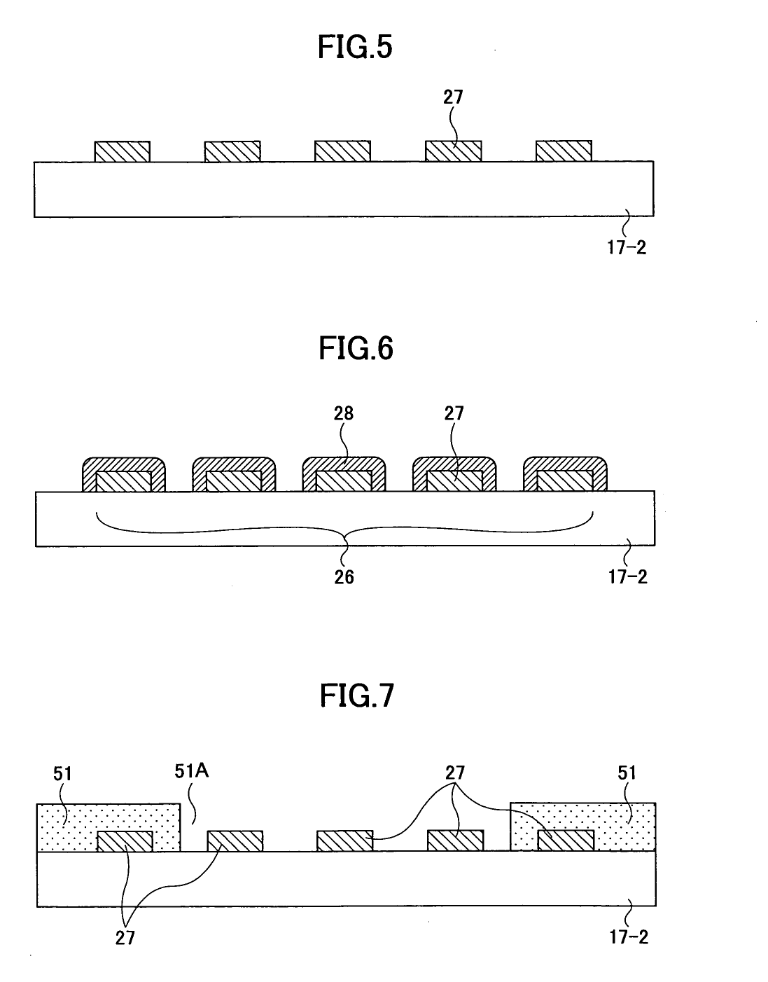

In the following, referring to FIGS. 5 and 6, a method of fabricating the inductor 26 shown in FIG. 1 is described as an exemplary method of fabricating an inductor.

FIG. 5 is a diagram illustrating a wiring formation step, and FIG. 6 is a diagram illustrating an electrodeposited resin formation step for covering the wiring with electrodeposited resin.

First, as is shown in FIG. 5, patterning is conducted to form the Cu wiring 27 into a comb-shaped structure on the resin layer 17-2. It is noted that the Cu wiring 27 may be formed through lithography and plating, for example. Then, as is shown in FIG. 6, the electrodeposited resin 28 including high magnetic permeability metal powder is formed through an electrodeposition process to cover the upper and side surfaces of the Cu wiring 27 formed on the resin layer 17-2. It is noted that the electrodeposition process may be realized inside an electrodeposition tank by inducing colloidal dispersion of polyimide resin including ferrite (corresponding to a high magnetic permeability filler material) in isopropyl alcohol corresponding to a solvent, and the substrate 10 may be immersed in the electrodeposition tank. The electrodeposition tank and the substrate 10 may be handled as electrodes, and an electric field at a predetermined level may be applied to the electrodes to form the electrodeposited resin 28.

By conducting the electrodeposition process as is described above, polyimide resin including high magnetic permeability filler material may cover the Cu wiring 27 to form the inductor 26. It is noted that in FIGS. 5 and 6, the electrodeposited resin 28 is arranged to cover the entire upper and side surfaces of the Cu wiring 27. However, the present invention is not limited to such an arrangement, and the electrodeposited resin 28 may also be formed at one or more portions of the Cu wiring 27.

In the following, a method of fabricating an inductor 54 having the electrodeposited resin 28 including high magnetic permeability filler material formed at selected portions of the Cu wiring 27 is described with reference to FIGS. 7˜9.

FIGS. 7˜9 are diagrams illustrating process steps for fabricating the inductor 54 having electrodeposited resin formed at selected wiring portions.

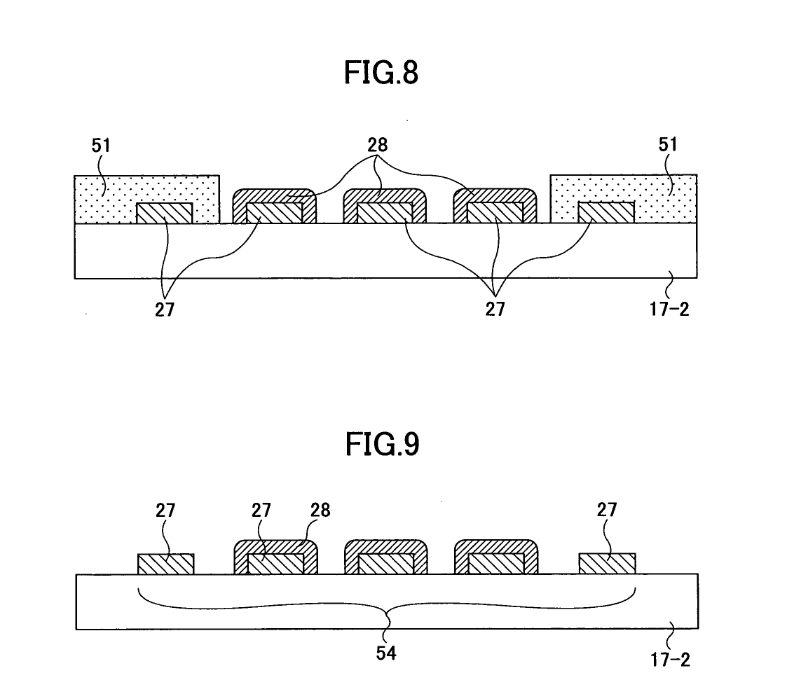

According to the present example, first, the Cu wiring 27 is formed into a comb-shaped structure as in the previous example (see FIG. 5). Then, as is shown in FIG. 7, patterning is conducted to form a resist layer 51 that includes an opening 51A exposing portions of the Cu wiring 27 on which the electrodeposited resin 28 is to be formed. Then, as is shown in FIG. 8, the electrodeposited resin 28 including high magnetic permeability filler material is formed through electrodeposition on the structure shown in FIG. 7. Then, as is shown in FIG. 9, the resist layer 51 is removed by a resist remover so that the inductor 54 having the electrodeposited resin 28 formed at selected portions of the Cu wiring 27 may be formed.

As can be appreciated from the above descriptions, by arranging the electrodeposited resin 28 including a high magnetic permeability filler material to cover the Cu wiring 27, high inductance may be achieved in the inductor 26 compared to the conventional inductor that only includes wiring, and miniaturization may be realized in the inductor 26. It is noted that in the embodiments described above, the Cu wiring 27 is arranged into a comb-shaped structure. However, the present invention is not limited to such an arrangement, and for example, the Cu wiring 27 may also be arranged in to a spiral structure.

### Second Embodiment

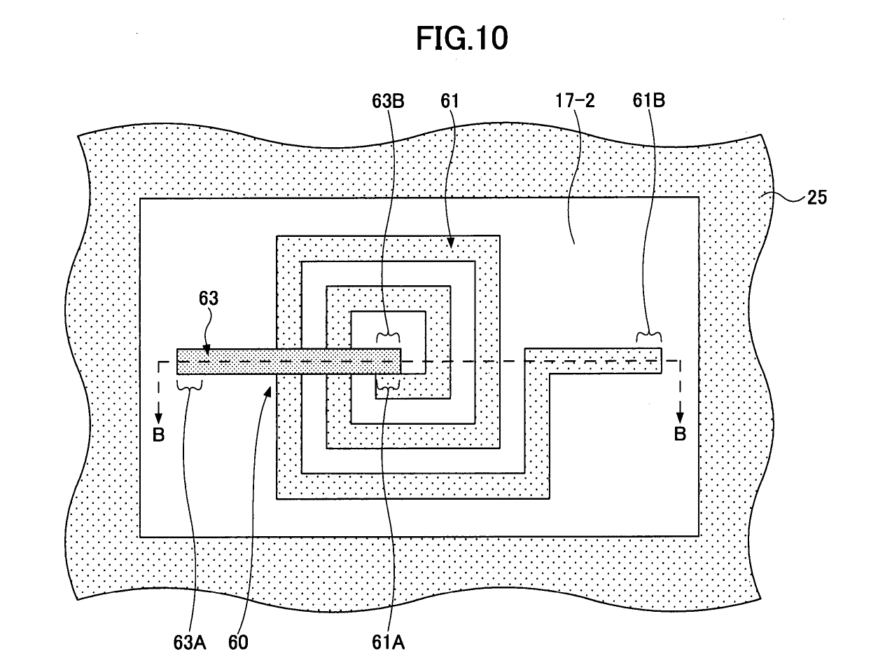

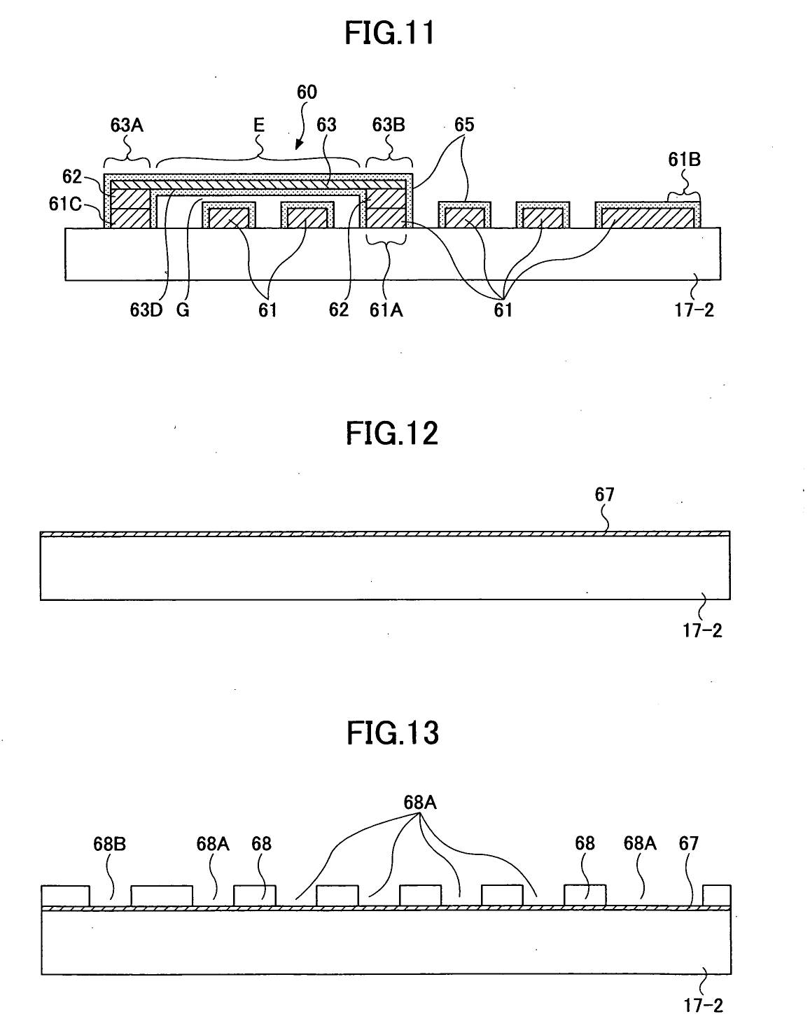

In the following, an inductor 60 according to a second embodiment of the present invention is described with reference to FIGS. 10 and 11.

FIG. 10 is a plan view of the inductor 60 according to the second embodiment, and FIG. 11 is a cross-sectional view of the inductor 60 cut across line B-B of FIG. 10. In FIGS. 10 and 11, components that are identical to those described in relation to the first embodiment are assigned the same references. It is noted that FIG. 10 illustrates a case in which the inductor 60 is formed on the resin layer 17-2 of the buildup layer 12. Also, it is noted that a region E shown in FIG. 11 represents a portion of a plate wiring part 63 that is not supported by a support part 62.

The inductor 60 includes a spiral wiring part 61 and a wiring part 61C corresponding to first wiring, support parts 62 and the plate wiring part 63 corresponding to second wiring, and electrodeposited resin 65 including a high magnetic permeability filler material. The spiral wiring part 61 is formed into a spiral structure on a resin layer 17-2. The spiral wiring part 61 includes two end portions 61A and 61B. The end portion 61A is located around the center of the spiral wiring part 61, and the end portion 61B is located at a position distanced away from an outermost periphery of the spiral wiring part 61 (e.g., right side of FIG. 10). The wiring part 61C is located at another position that is distanced away from the outermost periphery of the spiral wiring part 61 (e.g., left side of FIG. 10) and is electrically connected to the support part 62.

The end portion 61B of the spiral wiring part 61 and the wiring portion 61C are electrically connected to the wirings 20. The spiral wiring part 61 and the wiring part 61C may be made of a Cu film that is arranged to have a film thickness of 20˜30 μm, for example.

The support parts 62 are formed on the upper surface of the end portion 61A of the spiral wiring part 61 and the upper surface of the wiring part 61C, respectively, and are electrically connected to the spiral wiring part 61 and the wiring part 61C, respectively. The support parts 62 may be made of a Cu film that is arranged to have a film thickness of 20˜30 μm, for example.

The plate wiring part 63 includes end portions 63A and 63B that are supported by and electrically connected to the support parts 62, and is arranged to be formed above the spiral wiring part 61. Also, the portion of the plate wiring part 63 corresponding to region E is spaced apart from the spiral wiring part 61 by space G.

According to the present embodiment, a mounting region for the plate wiring part 63 does not have to be separately provided on the resin layer 17-2; that is, a region above the region at which the spiral wiring part 61 is formed may be used to form the plate wiring part 63 so that a long wiring length may be secured for the wiring realizing the inductor 60 while realizing miniaturization of the inductor 60.

The electrodeposited resin 65 including a high magnetic permeability filler material is arranged to cover wiring structure including the spiral wiring part 61, the wiring part 61C, the support parts 62, and the plate wiring part 63. In this case, the electrodeposited resin 65 including a high magnetic permeability filler material is also arranged to cover the lower surface 63D of the plate wiring part 63 portion corresponding to the region E. It is noted that material with a magnetic permeability of at least 100 is preferably used as the high magnetic permeability material. For example, ferrite (permeability μ=2000), Fe, Ni, Fe—Ni alloy, or Permalloy, may be used as the high magnetic permeability material. Also, it is noted that the filler made of the high magnetic permeability material may be arranged to have a dimension of a few μm or lower, for example. As for the resin material making up the electrodeposited resin 65, for example, polyimide resin or epoxy resin may be used.

According to the present embodiment, by providing the electrodeposited resin 65 including a high magnetic permeability filler material that covers the wiring structure including the spiral wiring part 61, the wiring part 61C, the support parts 62, and the plate wiring part 63, high inductance may be realized in the inductor 60, and the strength of the inductor 60 may be increased.

In the following, referring to FIGS. 12˜21, a method of fabricating the inductor 60 on the resin layer 17-2 of the buildup layer 12 is described as an exemplary method of fabricating the inductor 60 of the second embodiment.

FIGS. 12˜21 are diagrams illustrating process steps for fabricating the inductor 60 of the second embodiment.

First, as is shown in FIG. 12, a seed layer 67 is formed on the resin layer 17-2. It is noted that a Cu film that is formed through an electroless plating process, for example, may be used as the seed layer 67. Also, the film thickness of the seed layer 67 may be arranged to be around 1˜2 μm. Then, as is shown in FIG. 13, a resist film 68 including an opening 68A for forming the spiral wiring part 61 and an opening 68B for forming the wiring part 61C is formed on the seed layer 67. It is noted that the film thickness of the resist film may be arranged to be substantially equal to the thickness of the spiral wiring part 61 and the wiring part 61C (e.g., 20˜30 μm).

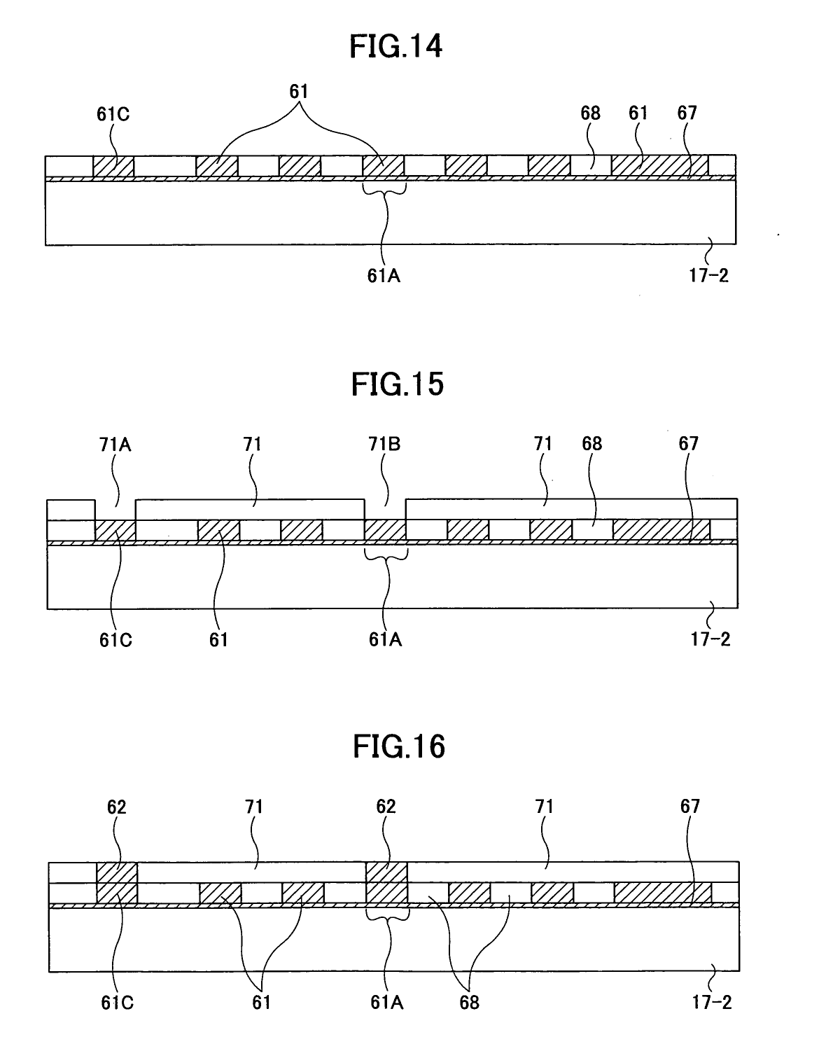

Then, as is shown in FIG. 14, a Cu film is filled into the openings 68A and 68B of the resist film 68 through an electrolytic plating process using the seed layer 67 as a power supply layer so that the spiral wiring part 61 and the wiring part 61C may be simultaneously formed. Then, as is shown in FIG. 15, a resist film 71 including openings 71A and 71B for forming the support parts 62 is formed on the structure shown in FIG. 14. The opening 71A is arranged to expose the upper surface of the wiring part 61C, and the opening 71B is arranged to expose the upper surface of the end portion 61A of the spiral wiring part 61. It is noted that the film thickness of the resist film 71 may be arranged to be substantially equal to the thickness of the support parts 62 (e.g., 20˜30 μm).

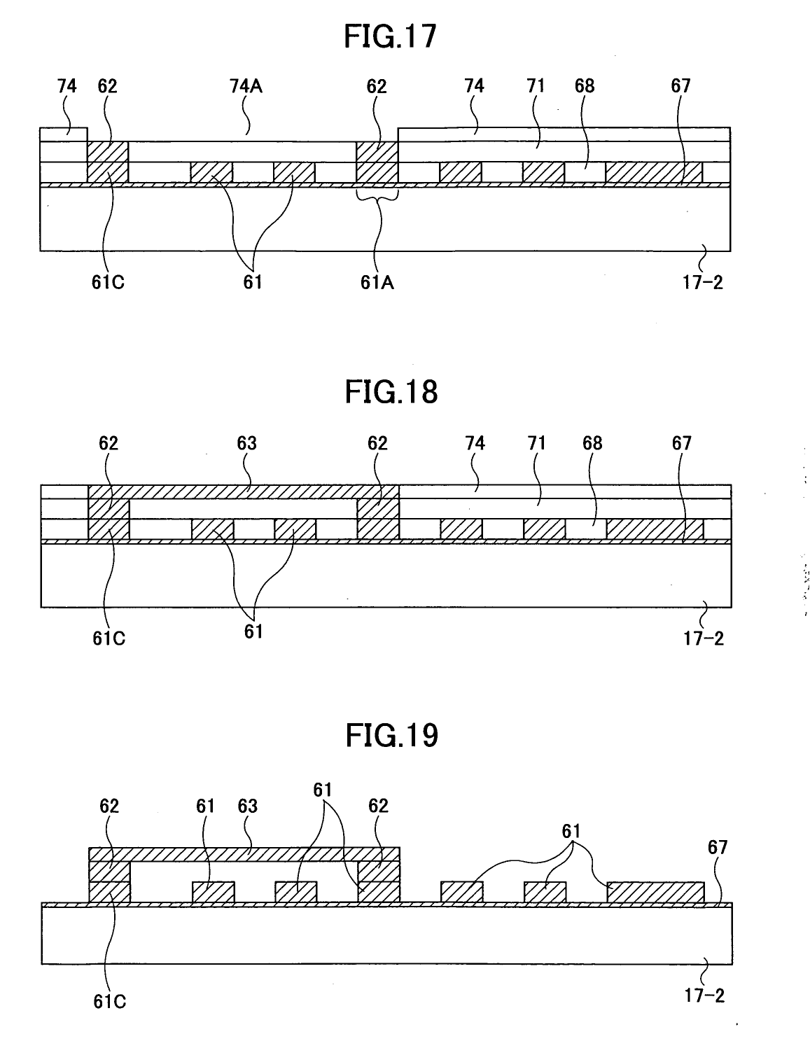

Then, as is shown in FIG. 16, a Cu film is filled into the openings 71A and 71B of the resist film 71 through an electro plating process so that two support parts 62 may be formed. Then, as is shown in FIG. 17, a resist film 74 including an opening 74A for forming the plate wiring part 63 is formed on the structure shown in FIG. 16. It is noted that the film thickness of the resist film 74 may be arranged to be substantially equal to the thickness of the plate wiring part 63 (e.g., 20˜30 μm).

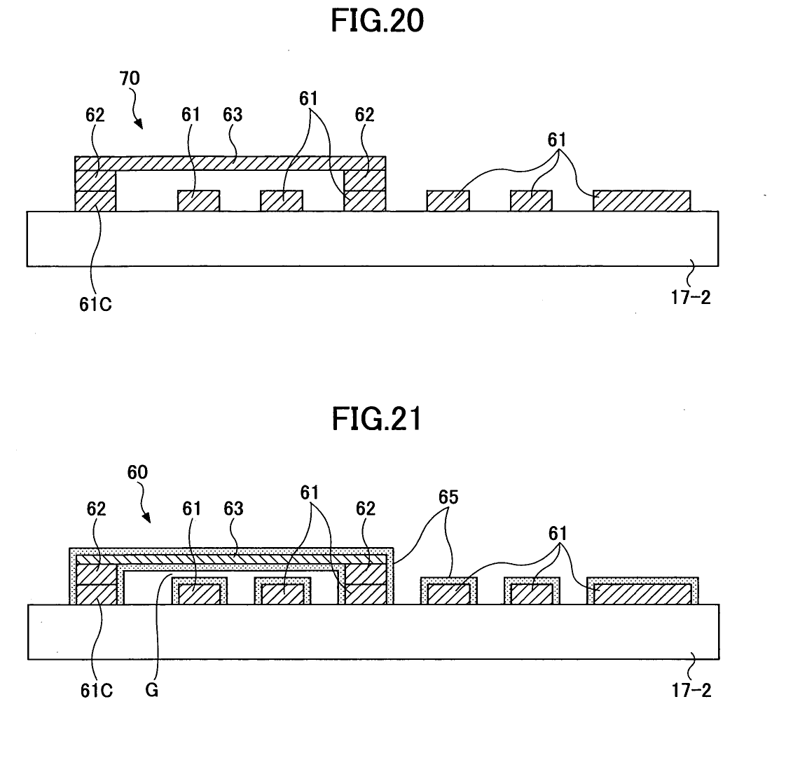

Then, as is shown in FIG. 18, a Cu film is filled into the opening 74A of the resist film 74 through an electro plating process to form the plate wiring part 63. Then, as is shown in FIG. 19, the resist films 68, 71, and 74 are removed by a resist remover. Then, etching is conducted to remove the seed layer 67, and in this way, a wiring structure 70 as is shown in FIG. 20 may be formed. Then, as is shown in FIG. 21, the electrodeposited resin 65 that covers the wiring structure 70 is formed through an electrodeposition process so that the inductor 60 may be formed. It is noted that the electrodeposition process may be realized inside an electrodeposition tank by inducing colloidal dispersion of polyimide resin including ferrite (corresponding to a high magnetic permeability filler material) in isopropyl alcohol corresponding to a solvent, and the substrate 10 may be immersed in the electrodeposition tank. The electrodeposition tank and the substrate 10 may be handled as electrodes, and an electric field at a predetermined level may be applied to the electrodes to form the electrodeposited resin 65.

As can be appreciated from the above descriptions, by using the region above the region at which the spiral wiring part 61 is formed to form the plate wiring part 63 supported by the support parts 62, and providing the electrodeposited resin 65 including a high magnetic permeability filler material that covers the wiring structure 70 including the spiral wiring part 61, the wiring part 61C, the support parts 62, and the plate wiring part 63, high inductance may be achieved at the inductor 60, and miniaturization of the inductor 60 may be realized.

It is noted that in the above described embodiments, the wiring structure 70 including the spiral wiring part 61, the wiring part 61C, the support parts 62, and the plate wiring part 63 is formed through electro plating; however, the present invention is not limited to such method, and for example, the wiring structure may also be formed through an imprinting process. Also, in the above described example, the inductor 60 is formed on the resin layer 17-2 corresponding to the uppermost layer of the buildup layer 12. However the present invention is not limited to such an arrangement, and for example, the inductor 60 may also be formed at an internal layer of the buildup layer 12. In another example, the inductor 60 may be formed at an internal layer or outer layer of the buildup layer 13. Also, the electrodeposited resin 65 may be provided at one or more selected portions of the wiring structure 70.

Further, the present invention is not limited to the specific embodiments described above, and variations and modifications may be made without departing from the scope of the present invention. It is noted that in one example, a communication antenna may be provided at the substrate 10 for establishing communication between a non-contact type IC tag or a non-contact type IC card and the LSI chip 45 mounted on the substrate 10. In such a case, the inductors 26, 54, and 60 that are described above in relation to the first and second embodiments of the present invention may be used in such a communication antenna. Also, the inductors 26, 54, and 60 may be formed on the LSI chip 45 for the IC tag or IC card via an insulating layer. In such a case, the LSI chip may be regarded as a substrate implementing an inductor.

The present application is based on and claims the benefit of the earlier filing date of Japanese Patent Application No. 2004-152341 filed on May 21, 2004, the entire contents of which are hereby incorporated by reference.

1. A substrate comprising:
an inductor that is realized by first wiring; and
resin including high magnetic permeability filler material which resin covers the first wiring.

2. The substrate as claimed in claim 1, further comprising:
second wiring that is provided at a region positioned above a region at which the first wiring is formed, the second wiring being electrically connected to the first wiring;
wherein the resin including high magnetic permeability filler material is arranged to cover the second wiring.

3. The substrate as claimed in claim 1, wherein
the resin corresponds to electrodeposited resin that is formed through electrodeposition.

4. A semiconductor device comprising:
a substrate including an inductor that is realized by first wiring, and resin including high magnetic permeability filler material which resin covers the first wiring; and
a semiconductor element that is mounted on the substrate.

5. A method of fabricating a substrate including an inductor realized by wiring, the method comprising:
a wiring formation step for forming the wiring; and
an electrodeposited resin formation step for forming resin including high magnetic permeability filler material through electrodeposition which resin covers the wiring.

6. The method of fabricating a substrate as claimed in claim 5, wherein the wiring formation step includes a first wiring formation step for forming first wiring; and
a second wiring formation step for forming second wiring that is provided at a region positioned above a region at which the first wiring is formed, the second wiring being electrically connected to the first wiring;
wherein a space is created between the first wiring and the second wiring.
